(19) United States
(12) Patent Application Publication
(10) Pub. No.: US 2024/0206059 A1
(43) Pub. Date: Jun. 20, 2024

(54) LOW-DIELECTRIC BOARD MATERIAL

(71) Applicant: NITTO DENKO CORPORATION, Ibaraki-shi, Osaka (JP)

(72) Inventors: Taku IMAIZUMI, Ibaraki-shi, Osaka (JP); Akihito MATSUTOMI, Ibaraki-shi, Osaka (JP); Naoto NAGAMI, Ibaraki-shi, Osaka (JP)

(21) Appl. No.: 18/287,344

(22) PCT Filed: Apr. 14, 2022
(86) PCT No.: PCT/JP2022/017795

§ 371 Date: Oct. 18, 2023

(30) Foreign Application Priority Data
Apr. 19, 2021 (JP) 2021-070654
Apr. 19, 2021 (JP) 2021-070655
Apr. 19, 2021 (JP) 2021-070656
Apr. 19, 2021 (JP) 2021-070657
Apr. 19, 2021 (JP) 2021-070658
Jan. 28, 2022 (JP) 2022-012215
Feb. 1, 2022 (JP) 2022-014324

(51) Int. Cl. H05K 1/03; C09D 7/65; C09D 179/08

(52) U.S. Cl. CPC H05K 1/0346; C09D 7/65; C09D 179/08; H05K 1/0353; H05K 2201/0116; H05K 2201/015; H05K 2201/0154

(57) ABSTRACT

A low-dielectric board material includes a metal layer and a porous resin layer disposed on a one-side surface of the metal layer in the thickness direction. The porous resin layer includes a first region, a second region, a third region, and a fourth region that are located in sequence toward a direction away from the metal layer when the porous resin layer is equally divided into four in the thickness direction. The first region has a plurality of closed cells that are separate from each other in a resin matrix. The average of the aspect ratios AR of the plurality of closed cells in the first region is 0.80 or more and 1.20 or less. The average of the aspect ratios AR is a ratio (L1/L2) of a length L1 of a closed cell in a direction orthogonal to the thickness direction to a length L2 of the closed cell in the thickness direction in a cross-sectional view.

### TECHNICAL FIELD

The present invention relates to a low-dielectric board material.

### BACKGROUND ART

There has been a known low-dielectric board material including a metal layer and a porous resin layer disposed on a one-side surface of the metal layer in the thickness direction (for example, see Patent document 1 below).

The low-dielectric board material is processed, for example, into a flexible wiring board.

### CITATION LIST

### Patent Document

Patent Document 1: Japanese Unexamined Patent Publication No. 2019-123851

### SUMMARY OF THE INVENTION

### Problem to be Solved by the Invention

Such low-dielectric board materials are required to have excellent processability. However, the low-dielectric board material described in Patent Document 1 does not have enough of the above required physical property.

The present invention provides a low-dielectric board material with excellent processability.

### Means for Solving the Problem

The present invention [1] includes a low-dielectric board material including: a metal layer; and a porous resin layer disposed on a one-side surface of the metal layer in a thickness direction, wherein the porous resin layer includes a first region, a second region, a third region, and a fourth region that are located in sequence toward a direction away from the metal layer when the porous resin layer is equally divided into four in the thickness direction, wherein at least the first region has a plurality of closed cells that are separate from each other in a resin matrix, and wherein an average of aspect ratios (L1/L2) of the closed cells in the first region is 0.80 or more and 1.20 or less, and the aspect ratio (L1/L2) is a ratio of a length L1 of a closed cell in a direction orthogonal to the thickness direction to a length L2 of the closed cell in the thickness direction in a cross-sectional view.

### Effects of the Invention

The low-dielectric board material of the present invention has excellent processability.

### BRIEF DESCRIPTION OF THE DRAWINGS

FIG. 1 is a cross-sectional view of one embodiment of the low-dielectric board material of the present invention.

FIG. 2 is a cross-sectional view of a variation of the low-dielectric board material.

FIG. 3 is a view of a processed image of an SEM picture of the low-dielectric board material of Example 1.

FIG. 4 is a view of a processed image of an SEM picture of the low-dielectric board material of Example 2.

FIG. 5 is a view of a processed image of an SEM picture of the low-dielectric board material of Comparative Example 1.

FIG. 6 is a view of a processed image of an SEM picture of the low-dielectric board material of Comparative Example 2.

### DESCRIPTION OF THE EMBODIMENT

### 1. Low-Dielectric Board Material 1

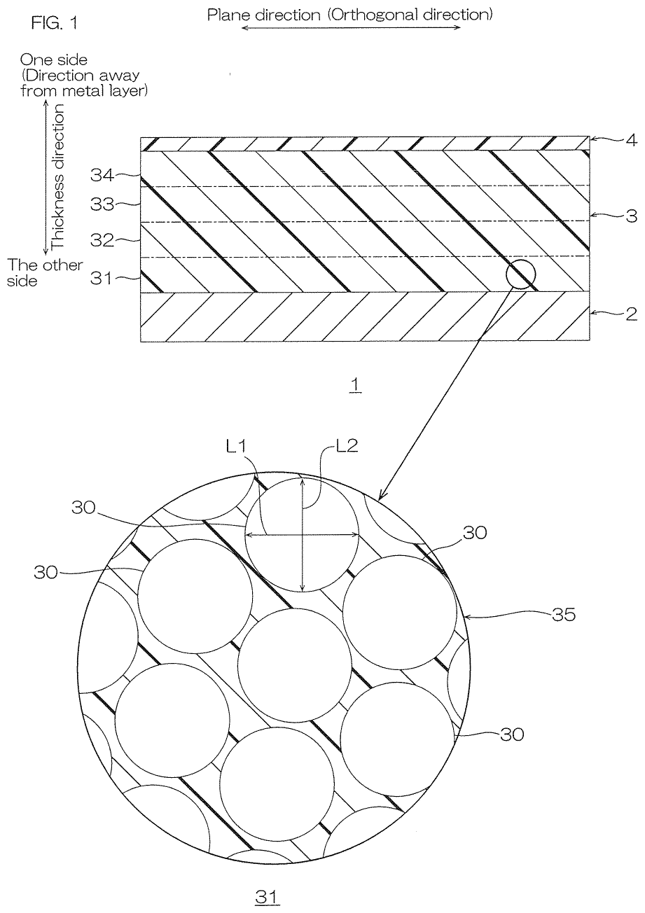

One embodiment of the low-dielectric board material of the present invention is described with reference to FIG. 1.

A low-dielectric board material 1 has a thickness. The low-dielectric board material 1 extends in a plane direction. The plane direction is orthogonal to a thickness direction. The low-dielectric board material 1 is in the shape of a board. The low-dielectric board material 1 has flexibility. The thickness of the low-dielectric board material 1 is not especially limited. The low-dielectric board material 1 has a thickness of, for example, 5 μm or more, and, for example, 2,000 μm or less.

### 1.1 Layer Structure of Low-Dielectric Board Material 1

The low-dielectric board material 1 includes a metal layer 2, a porous resin layer 3, and a skin layer 4 in sequence toward one side in the thickness direction. In other words, the low-dielectric board material 1 includes the metal layer 2, the porous resin layer 3 disposed on a one-side surface of the metal layer 2 in the thickness direction, and the skin layer 4 disposed on a one-side surface of the porous resin layer 3 in the thickness direction. In the present embodiment, the low-dielectric board material 1 preferably includes only the metal layer 2, the porous resin layer 3, and the skin layer 4.

### 1.2 Metal Layer 2

The metal layer 2 is disposed at the other edge portion of the low-dielectric board material 1 in the thickness direction. The metal layer 2 forms the other-side surface of the low-dielectric board material 1 in the thickness direction. The metal layer 2 extends in the plane direction. Specifically, the metal layer 2 is a metal film. Examples of the metal include copper, iron, silver, gold, aluminum, nickel, and alloys thereof (stainless steels and bronze). As the metal, copper is preferable. The metal layer 2 has a thickness of, for example, 0.1 μm or more, preferably 1 μm or more, and, for example, 100 μm or less, preferably 50 μm or less.

### 1.3 Porous Resin Layer 3

The porous resin layer 3 is in contact with the one-side surface of the metal layer 2 in the thickness direction. The porous resin layer 3 has a thickness. The porous resin layer 3 extends in the plane direction. The porous resin layer 3 has a plurality of closed cells 30 that are separate from each other in a resin matrix throughout in the thickness direction. The closed cells 30 are completely covered with the resin matrix and do not communicated with their adjacent cells. Further, each of the closed cells 30 is not an open cell of which inside faces the metal layer 2 or the skin layer 4.

When being divided equally into four in the thickness direction, the porous resin layer 3 includes a first region 31, a second region 32, a third region 33, and a fourth region 34 in sequence toward a direction away from the metal layer 2. In the porous resin layer 3, the first region 31, the second region 32, the third region 33, and the fourth region 34 are located in sequence toward one side in the thickness direction.

### 1.3.1 First Region 31

The first region 31 is the outermost side of the porous resin layer 3 located on the other side of the porous resin layer 3 in the thickness direction. The first region 31 is in contact with the one-side surface of the metal layer 2 in the thickness direction. The first region 31 has the above-described closed cells 30.

The average of the aspect ratios of the plurality of closed cells 30 in the first region 31 is 0.80 or more and 1.20 or less.

When the average of the aspect ratios AR of the plurality of closed cells 30 in the first region is less than 0.80 or more than 1.20, the processability of the low-dielectric board material 1 decreases. The processability includes a quality to make the physical properties less likely to change even when the precursor film is cured by heating before the complete curing (described below) or further the low-dielectric board material 1 is pressed. The physical properties include the thickness, dielectric constant, and/or dielectric loss tangent of the porous resin layer 3.

The above-described aspect ratio AR is a ratio of a length L1 of a closed cell 30 in an orthogonal direction to a length L2 of the closed cell 30 in the thickness direction in a cross-sectional view of the porous resin layer 3. The orthogonal direction is orthogonal to the thickness direction and corresponds to a right-left direction of FIG. 1.

The average of the aspect ratios AR of the plurality of closed cells 30 in the first region is preferably 0.85 or more, more preferably 0.90 or more, even more preferably 0.95 or more and further, preferably 1.15 or less, more preferably 1.10 or less, even more preferably 1.05 or less. When the average of the aspect ratios AR of the plurality of closed cells 30 in the first region is the above-described upper limit or less or the above-described lower limit or more, the processability of the low-dielectric board material 1 can further be improved.

The average of the longitudinal cell lengths of the closed cells 30 is, for example, 1 μm or more and 100 μm or less. The average of the longitudinal cell lengths of the closed cells 30 corresponds to a cell diameter when the average of the aspect ratios AR is 1.

The first region 31 may include the above-described open cell in addition to the closed cells 30.

### 1.3.2 Second Region 32 to Fourth Region 34

Each of the second region 32, the third region 33, and the fourth region 34 has the same structure of that of the above-described first region 31. However, the average of the aspect ratios AR of the plurality of closed cells 30 in each of the second region 32, the third region 33, and the fourth region 34 is, for example, 0.80 or more and 1.20 or less.

In view of the production method described below, among the first region 31 to fourth region 34, the average of the aspect ratios AR in the first region 31 tends to be far away from 1.0. However, according to the present invention, among the first region 31 to fourth region 34, by setting the average of the aspect ratios AR to 0.80 or more and 1.20 or less in the first region 31, the average of the aspect ratios AR in the second region 32 to fourth region 34 also naturally becomes 0.80 or more and 1.20 or less.

Further, the average of the longitudinal cell lengths of the closed cells 30 in the second region 32 to fourth region 34 is, for example, larger than or equal to that in the first region 31.

### 1.3.3 Material of Porous Resin Layer 3

The material of the porous resin layer 3 is resin. The resin is not limited. Specifically, examples of the resin include polycarbonate resin, polyimide resin, polyimide fluoride resin, epoxy resin, phenol resin, urea resin, melamine resin, diallyl phthalate resin, silicone resin, thermosetting urethane resin, fluorine resin (including polytetrafluoroethylene (PTFE)), and a liquid crystal polymer (LCP). These can be used alone or in combination of two or more. Among the above-described resins, polyimide resin is preferable. The details of the polyimide resin including its physical properties and production method are described in, for example, WO2018/186486 and Japanese Unexamined Patent Publication No. 2020-172667. Polyimide resin may merely be referred to as polyimide.

### 1.3.4 Other Physical Properties of Porous Resin Layer 3

After the porous resin layer 3 is heated at 450° ° C. for 1 hour, the rate of decrease in mass is, for example, 3.0% by mass or less, preferably 2.0% by mass or less, more preferably 1.8% by mass or less and, for example, 0.1% by mass or more, preferably 1.5% by mass or more.

When the rate of decrease in mass of the porous resin layer 3 is the above-described upper limit or less, the change in the dielectric constant and/or dielectric loss tangent of the porous resin layer 3 due to heating and/or pressing can be suppressed. The method of measuring the rate of decrease in mass of the porous resin layer 3 is described in Examples below.

When the porous resin layer 3 consists of polyimide, the rate of imidization of the porous resin layer 3 is, for example, 0.920 or more, preferably, 0.950 or more.

When the rate of imidization of the porous resin layer 3 is the above-described lower limit or more, the change in the dielectric constant and/or the dielectric loss tangent of the porous resin layer 3 at a thermal process can be suppressed. The method of measuring the rate of imidization of the porous resin layer 3 is described in Examples below.

The porous resin layer 3 has a porosity of, for example, 50% or more, preferably 60% or more, more preferably 70% or more. The porosity of the porous resin layer 3 is, for example, less than 100%, further 99% or less. When the porous resin layer 3 consists of polyimide, the porosity can be obtained using the following formula.

Porosity (%)=(1−Specific Gravity of Porous Resin Layer 3/Specific Gravity of Polyimide)×100

The dielectric constant of the porous resin layer 3 on the frequency 10 GHz is, for example, 1.63 or less, and, for example, 1.55 or more. The dielectric constant of the porous resin layer 3 is measured with a resonator method.

The dielectric loss tangent of the porous resin layer 3 on the frequency 10 GHz is, for example, 0.006 or less, preferably 0.005 or less, more preferably 0.004 or less, even more preferably 0.003 or less, and, for example, 0.002 or more. The dielectric loss tangent of the porous resin layer 3 is measured with a resonator method.

The porous resin layer 3 has a thickness of, for example, 2 μm or more, preferably 5 μm or more, and, for example, 1,000 μm or less, preferably 500 μm or less.

### 1.4 Skin Layer 4

The skin layer 4 is disposed at the one-edge portion of the low-dielectric board material 1 in the thickness direction. The skin layer 4 forms the one-side surface of the low-dielectric board material 1 in the thickness direction. The skin layer 4 extends in the plane direction. The skin layer 4 is in contact with the one-side surface of the porous resin layer 3 in the thickness direction. For example, the skin layer 4 is a dense film consisting of the same resin as that of the porous resin layer 3. The skin layer 4 has a thickness of, for example, 1 μm or more, and, for example, 50 μm or less. The skin layer 4 has a porosity of 0.1% or less, further, 0%.

### 1.5 Method of Producing Low-Dielectric Board Material 1

A method of producing the low-dielectric board material 1 is described.

First, a metal layer 2 is prepared.

Next, a varnish containing a precursor of the above-described resin, a porosity agent, a nucleation agent, and a solvent is prepared. Next, the varnish is applied to the one-side surface of the metal layer 2 in the thickness direction, thereby forming a coating film. The types, blending ratios, etc. of the porosity agent, nucleation agent, and solvent in the varnish are described, for example, in WO2018/186486.

A case in which the resin is polyimide is described. The precursor of polyimide is, for example, a reaction product of a diamine component and an acid dianhydride component. Examples of the diamine component include an aromatic diamine and an aliphatic diamine. In view of obtaining the tensile modulus of elasticity of the above-described upper limit or less, an aromatic diamine is preferable as the diamine component.

Further, the diamine component and the acid dianhydride component can be used alone or in combination. Specifically, as the diamine component, an aromatic diamine is preferably used alone.

Examples of the aromatic diamine include the first diamine, the second diamine, and the third diamine.

The first diamine contains a single aromatic ring. Examples of the first diamine include phenylenediamine, dimethylbenzene diamine, and ethylmethylbenzene diamine. Phenylenediamine is preferable. Examples of the phenylenediamine include o-phenylenediamine, m-phenylenediamine, and p-phenylenediamine. As the phenylenediamine, p-phenylenediamine is preferable. P-phenylenediamine may be abbreviated as PDA.

The second diamine contains a plurality of aromatic rings and an ether bond disposed between the aromatic rings. Examples of the second diamine include oxydianiline. Examples of oxydianiline include 3,4′-oxydianiline and 4,4′-oxydianiline. 4,4′-oxydianiline (also referred to as: 4,4-diaminodiphenyl ether) is preferable. 4,4′-oxydianiline may be abbreviated as ODA.

The third diamine contains a plurality of aromatic rings and an ester bond disposed between the aromatic rings. Examples of the third diamine include aminophenyl amino benzoate. 4-aminophenyl-4-amino benzoate is preferable. 4-aminophenyl-4-amino benzoate may be abbreviated as APAB.

In addition to the first diamine to the third diamine, examples of the aromatic diamine further include 4,4′-methylenedianiline, 4,4′-dimethylenedianiline, 4,4′-trimethylenedianiline, and bis(4-aminophenyl)sulfone.

The above-described diamine components can be used alone or in combination. As the diamine component, a combination of the first diamine, the second diamine, and the third diamine is preferable. A combination of p-phenylenediamine (PDA), 4,4′-oxydianiline (ODA), and 4-aminophenyl-4-amino benzoate (APAB) is more preferable.

The mol fraction of the first diamine in the diamine component is, for example, 10 mol % or more, preferably 20 mol % or more, and, for example, 70 mol % or less, preferably 65 mol % or less. The mol fraction of the second diamine in the diamine component is, for example, 5 mol % or more, preferably 10 mol % or more, and, for example, 40 mol % or less, preferably 30 mol % or less. The mol fraction of the third diamine in the diamine component is, for example, 5 mol % or more, for example, 10 mol % or more, and, for example, 40 mol % or less, preferably 30 mol % or less.

Further, with respect to 100 parts by mol of the total amount of the first diamine and the second diamine, the third diamine is, for example, 5 parts by mol or more, preferably 10 parts by mol or more, more preferably 20 parts by mol or more, and, for example, 100 parts by mol or less, preferably 50 parts by mol or less, more preferably 30 parts by mol or less.

The acid dianhydride component is not limited. The acid dianhydride component contains, for example, an acid dianhydride having an aromatic ring. Examples of the acid dianhydride having an aromatic ring include an aromatic tetracarboxylic acid dianhydride. Examples of the aromatic tetracarboxylic acid dianhydride include benzene tetracarboxylic acid dianhydride, benzophenone tetracarboxylic acid dianhydride, biphenyl tetracarboxylic acid dianhydride, biphenyl sulfonetetracarboxylic acid dianhydride, and naphthalene tetracarboxylic acid dianhydride. These can be used alone or in combination. As the acid dianhydride having an aromatic ring, biphenyl tetracarboxylic acid dianhydride is preferable. Examples of the biphenyl tetracarboxylic acid dianhydride include 3,3′-4,4′-biphenyl tetracarboxylic acid dianhydride, 2,2′-3,3′-biphenyl tetracarboxylic acid dianhydride, 2,3,3′,4′-biphenyl tetracarboxylic acid dianhydride, and 3,3′,4,4′-diphenylethertetracarboxylic acid dianhydride. As the biphenyl tetracarboxylic acid dianhydride, 3,3′-4,4′-biphenyl tetracarboxylic acid dianhydride is preferable. 3,3′-4,4′-biphenyl tetracarboxylic acid dianhydride may be abbreviated as BPDA.

The ratios of the diamine component and the acid dianhydride component are adjusted so that the molar amount of the amino group (—NH₂) of the diamine component is, for example, equivalent to the molar amount of the acid anhydride group (—CO—O—CO—) of the acid dianhydride component.

To prepare the precursor of polyimide, the above-described diamine component, the above-described acid dianhydride component, and a solvent are blended, thereby preparing a varnish. The varnish is heated, thereby preparing a solution of the precursor. Subsequently, a nucleation agent and a porosity agent are blended into the precursor solution, thereby preparing a porous precursor solution.

Thereafter, the porous precursor solution is applied to the one-side surface of the metal layer 2 in the thickness direction, thereby forming a coating film.

Thereafter, the coating film is dried by heating, thereby forming a precursor film. While advancing the removal of the solvent, the above-described heating enables the preparation of a precursor film having a phase-separated structure of the polyimide precursor and porosity agent with the nucleation agent as its nucleus. Further, the heating of the coating film forms the skin layer 4 on the one-side surface of the precursor film in the thickness direction. The heating time is, for example, 160° C. or less. The heating time is, for example, 1000 seconds or less.

Thereafter, for example, with a supercritical extraction method using supercritical carbon dioxide as a solvent, the porosity agent is extracted (pulled or removed) from the precursor film. In this manner, the porous resin layer 3 before curing is prepared.

Thereafter, the precursor film is cured by heating. In other words, the imidization of the precursor film is advanced. The temperature is, for example, 340° C. or more, preferably 350° C. or more, more preferably 360ºC or more, and, for example, 410° C. or less, preferably 390° C. or less, more preferably 380° C. or less, even more preferably 370° C. or less. When the temperature is the above-described lower limit or more, the porous resin layer 3 with the above-described average of the aspect ratios AR can be formed while the rate of decrease in mass of the porous resin layer 3 decreases, and the rate of imidization appropriately increases. When the temperature is the above-described upper limit or less, the porous resin layer 3 with the above-described average of the aspect ratios AR can be formed.

In this manner, the porous resin layer 3 consisting of the polyimide after curing is formed.

As described above, a low-dielectric board material 1 is produced.

### 1.6 Use of Low-Dielectric Board Material 1

The use of the low-dielectric board material 1 is not limited. The low-dielectric board material 1 is processed, for example, into a flexible wiring board. In the process, the low-dielectric board material 1 is, for example, pressed in the thickness direction.

Further, before or after the pressing, the metal layer 2 is, for example, etched and patterned.

### 2. Operations and Effects of One Embodiment

In the low-dielectric board material 1, the average of the aspect ratios of the plurality of closed cells 30 in the first region 31 is, 0.80 or more and 1.20 or less, and thus the low-dielectric board material 1 has excellent processability.

Specifically, the change in the thickness of the porous resin layer 3 before and after the pressing in the process of the low-dielectric board material 1 can be suppressed. Further, the change in the dielectric constant and/or dielectric loss tangent of the porous resin layer 3 can be suppressed.

### 3. Variations

In each of the variations, the same members and steps as in one embodiment are given the same reference numerals and the detailed descriptions thereof are omitted. Further, the variations can have the same operations and effects as those of one embodiment unless especially described otherwise. Furthermore, one embodiment and variations can appropriately be combined.

### 3.1 First Variation

The precursor film before heating (curing) may be treated as the porous resin layer 3.

The low-dielectric board material 1 including the above-described precursor film as the porous resin layer 3 can suppress the change in the thickness due to the subsequent heating (curing).

### 3.2 Second Variation

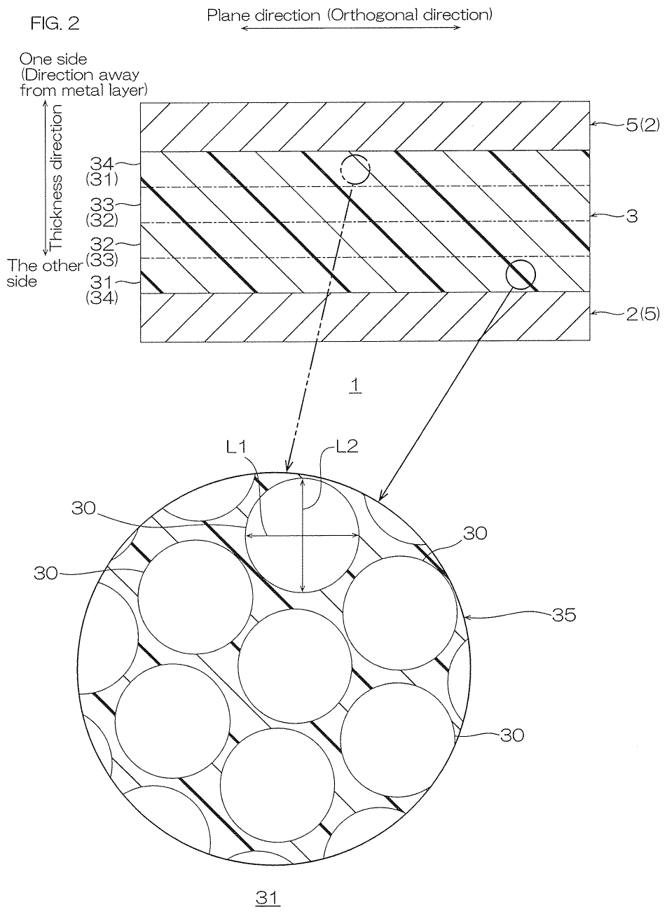

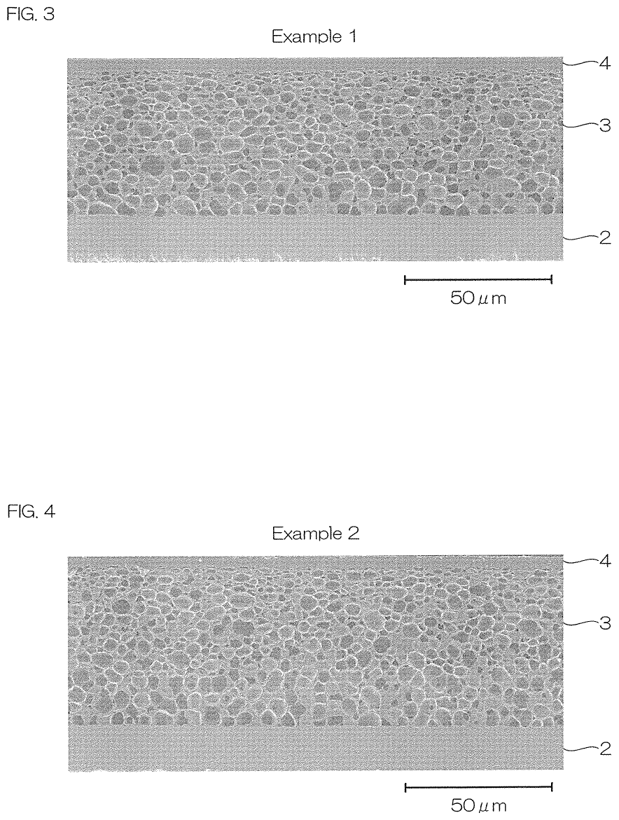

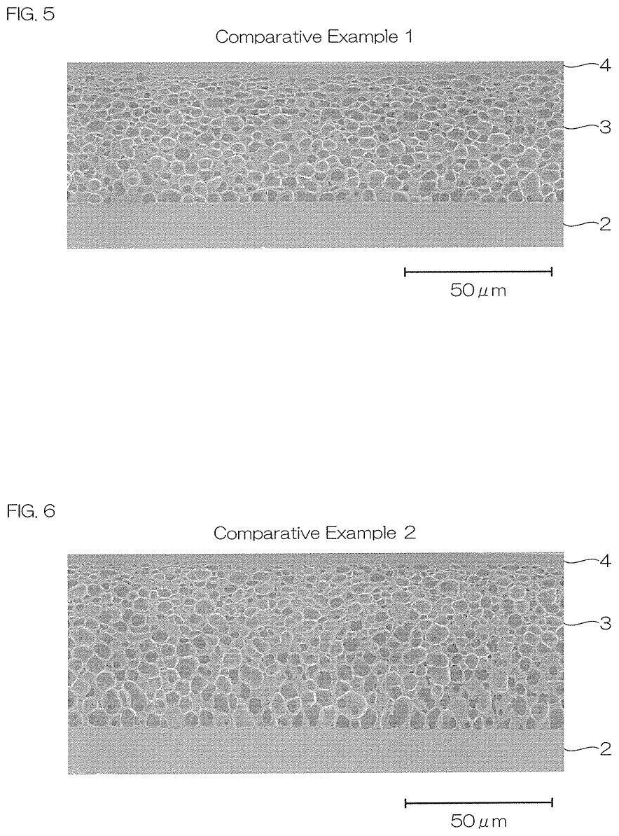

In the first variation, as illustrated in FIG. 2, the low-dielectric board material 1 does not include a skin layer 4 and may further include an alternative metal layer 5. The alternative metal layer 5 is disposed at the other edge portion of the low-dielectric board material 1 in the thickness direction.

In the porous resin layer 3, the alternative metal layer 5 is disposed on the one-side surface of the porous resin layer 3. Specifically, the alternative metal layer 5 is in contact with the one-side surface of the porous resin layer 3. The alternative metal layer 5 extends in the plane direction. The alternative metal layer 5 has the same structure as that of the metal layer 2.

For each of the two regions of the four equally-divided regions, one of which is the region adjacent to the metal layer 2 and the other of which is the region adjacent to the alternative metal layer 5 (phantom lines), the average of the aspect ratios AR is calculated. Then, the lower one of the calculated averages is defined as the average of the aspect ratios AR in the first region 31. In FIG. 2, a case where the region adjacent to the metal layer 2 is the first region 31 is enumerated outside the parentheses. In FIG. 2, a case where the region adjacent to the alternative metal layer 5 is the first region 31 is enumerated in the parentheses.

### 3.3 Other Variations

Although not illustrated, a low-dielectric board material 1 includes a metal layer 2 and a porous resin layer 3, and does not include a skin layer 4 and an alternative metal layer 5.

Although not illustrated, a low-dielectric board material 1 includes a metal layer 2, a porous resin layer 3, a skin layer 4, and an alternative metal layer 5.

Although not illustrated, the skin layer 4 may be disposed on the one-side surface and the other-side surface of the porous resin layer 3 in the thickness direction.

Although not illustrated, an adhesive agent layer may be disposed on the one-side surface and the other-side surface of the porous resin layer 3 in the thickness direction.

Although not illustrated, the skin layer 4 may be disposed on the one-side surface or the other-side surface of the porous resin layer 3 in the thickness direction.

### EXAMPLES

Next, the present invention is more specifically described with reference to Examples and Comparative Examples below. The present invention is not limited to Examples and Comparative Examples in any way. The specific numeral values used in the description below, such as blending ratios (content ratios), physical property values, and parameters, can be replaced with the corresponding blending ratios (content ratios), physical property values, and parameters in the above-described “DESCRIPTION OF THE EMBODIMENTS”, including the upper limit values (numeral values defined with “or less” or “less than”) or the lower limit values (numeral values defined with “or more” or “more than”).

### 1. Production of Low-Dielectric Board Material 1

### Example 1

0.66 mol of p-phenylenediamine (PDA) (the first diamine), 0.22 mol of 4,4′-oxydianiline (ODA) (the second diamine), and 0.22 mol of 4-aminophenyl-4-amino benzoate (APAB) (the third diamine) were dissolved with N-methyl-2-pyrrolidone (NMP), thereby preparing a diamine component solution. Subsequently, 1.00 mol of 3,3′-4,4′-biphenyl tetracarboxylic acid dianhydride (BPDA) was added to the diamine component solution, and stirred at 80° ° C. The stirring was stopped, and the stirred solution was left to cool, thereby preparing a polyimide precursor solution.

The concentration of the solid content of the polyimide precursor solution was 13% by mass.

With respect to 100 parts by mass of the polyimide precursor solution, 150 parts by mass of polyoxyethylene dimethyl ether (grade: MM400 manufactured by NOF CORPORATION) with a weight-average molecular weight of 400 as a porosity agent and 3 parts by mass of PTFE powder having a particle size of 1 μm or less as a nucleation agent were added. Then, they were stirred, thereby producing a homogeneous transparent solution. 4 parts by mass of 2-methylimidazole was added as an imidization catalyst to the produced solution, thereby preparing a varnish. The varnish was applied to the metal layer 2 consisting of a copper film, thereby forming a coating film. The coating film was dried by heating at 120 to 160° C. for 540 seconds, thereby removing NMP. In this manner, a polyimide precursor film with a thickness of approximately 50 μm was produced on the one-side surface of the metal layer 2 in the thickness direction.

Thereafter, with a supercritical extraction method using supercritical carbon dioxide as a solvent, the extraction removal of the porosity agent, the phase separation of the remaining NMP, and the formation of pores (closed cells) were accelerated. In this manner, a precursor film having pores was produced. Subsequently, the precursor film was imidized by heating at 360° C. In this manner, a low-dielectric board material 1 was produced.

### Example 2 and Comparative Examples 1 and 2

In the same manner as Example 1, a low-dielectric board material 1 was produced. However, the heating temperature at the imidization was changed according to Table 1.

### 2. Evaluations

The low-dielectric board material 1 of each of Examples and Comparative Examples was evaluated by the following items. The results are shown in Table 1.

### 2.1 Rate of Decrease in Mass of Porous Resin Layer 3

2 mg of the porous resin layer 3 was collected to produce a sample. The sample was heated at 450° C. for 1 hour. The rate of decrease in mass of the sample after heating was obtained based on the following formula.

[Mass of Sample before Heating−Mass of Sample after Heating]/(Mass of Sample after Heating)×100

### 2.2 Rate of Imidization of Porous Resin Layer 3

Using the device and method described below, the rate of imidization of the porous resin layer 3 was calculated as the intensity ratio of the peak obtained by an infrared absorption spectroscopy (IR).
Device: Nicolet IR-200
Measurement Conditions: ATR, the number of times of integration 128 times, resolution 2 cm⁻¹
Intensity Ratio of Imidization: measured from the intensity ratio of 1773 cm⁻¹ and 3064 cm⁻¹.
   Subsequently, using the porous resin layer 3 of Comparative Example 2 (product heated at 420° C.) as a completely-cured product, the rate of imide of each of Examples 1 and 2 and Comparative Example 1 was calculated with reference to the intensity ratio of the imidization of Comparative Example 2 as a criterion value (i.e., 1).

### 2.3 Average of Aspect Ratios AR of Closed Cells 30 in First Region 31

Using the device under the conditions described below, a cross-sectional SEM observation of the low-dielectric board material 1 was carried out to obtain an SEM image. The aspect ratios AR of all the closed cells 30 observed in the first region 31 of the SEM image were obtained to calculate the average of the ratios.
SEM Device: SU 8020, manufactured by Hitachi, Ltd.
Measurement condition: acceleration voltage 2.0 kV
Observation Magnification: ×750

### 2.4 Thickness of Porous Resin Layer 3

The thickness of the porous resin layer 3 was measured with a thickness tester (HKT-1200, manufactured by Fujiwork Co., Ltd.).

### 2.5 Change in Thickness of Porous Resin Layer 3

The low-dielectric board material 1 was heated at 450° C. for 1 hour. The thickness of the low-dielectric board material 1 after heating was obtained. Then, the change in the thickness of the low-dielectric board material 1 after heating was obtained.

Subsequently, the low-dielectric board material 1 after heating was pressed at 5 MPa for 5 minutes. The thickness of the low-dielectric board material 1 after the pressing was obtained. Then, the change in the thickness of the low-dielectric board material 1 after the pressing was obtained.

### 2.6 Dielectric Constant and Dielectric Loss Tangent of Porous Resin Layer 3

The dielectric constant and dielectric loss tangent of the porous resin layer 3 on 10 GHz were obtained using the device and method described below.
Device: PNA network analyzer (manufactured by Agilent Technologies) A Split Post Dielectric Resonator (SPDR) method was used.

TABLE 1

| | | | Comparative | Comparative |
|---|---|---|---|---|
| | Example 1 | Example 2 | Example 1 | Example 2 |
| Heating (Imidization) Temperature (° C.) | 360 | 380 | 330 | 420 |
| Rate of Decrease in Mass of Porous Resin | 1.7 | 1.3 | 4.2 | 1.4 |
| Layer (%) | | | | |
| Rate of Imidization of Porous Resin Layer | 0.972 | 0.994 | 0.917 | 1.000 |
| as IR Intensity Ratio | | | | |
| Average of Aspect Ratios AR of Closed | 1.01 | 0.80 | 1.38 | 0.60 |
| Cells in First Region of Porous Resin Layer | | | | |
| Change in Thickness of Low-dielectric | −0.7 | 3.8 | −6.5 | 9.7 |
| Board Material (after Heating) (%) | | | | |
| Change in Thickness of Low-dielectric | −0.4 | −0.6 | −0.7 | −3.5 |
| Board Material (after pressing) (%) | | | | |
| Dielectric Constant of Porous Resin Layer | 1.61 | 1.56 | 1.65 | 1.54 |
| Dielectric Loss Tangent of Porous Resin | 0.0025 | 0.0022 | 0.0069 | 0.0018 |
| Layer | | | | |

While the illustrative embodiments of the present invention are provided in the above description, such is for illustrative purpose only and it is not to be construed as limiting in any manner. Modification and variation of the present invention that will be obvious to those skilled in the art is to be covered by the following claims.

### INDUSTRIAL APPLICABILITY

The low-dielectric board material is processed into a flexible wiring board.

### DESCRIPTION OF REFERENCE NUMERALS

1 low-dielectric board material
2 metal layer
3 porous resin layer
5 metal layer

1. A low-dielectric board material comprising: a metal layer; and a porous resin layer disposed on a one-side surface of the metal layer in a thickness direction,
wherein the porous resin layer includes a first region, a second region, a third region, and a fourth region that are located in sequence toward a direction away from the metal layer when the porous resin layer is equally divided into four in the thickness direction,
wherein at least the first region has a plurality of closed cells that are separate from each other in a resin matrix, and
wherein an average of aspect ratios (L1/L2) of the closed cells in the first region is 0.80 or more and 1.20 or less, and the aspect ratio (L1/L2) is a ratio of a length L1 of a closed cell in a direction orthogonal to the thickness direction to a length L2 of the closed cell in the thickness direction in a cross-sectional view.
